(19) United States
(12) Patent Application Publication
(10) Pub. No.: US 2026/0229871 A1
(43) Pub. Date: Aug. 6, 2026

(54) NEW ENERGY POWER STATION GROUNDING PROTECTION SYSTEM, METHOD, ELECTRONIC DEVICE, AND STORAGE MEDIUM

(71) Applicant: Shanxi Yingrun New Energy Co., Ltd, Taiyuan (CN)

(72) Inventors: Pengpeng JIA, Taiyuan (CN); Jingshun WANG, Taiyuan (CN); Guang WANG, Taiyuan (CN); Ziheng LEI, Taiyuan, Shanxi (CN)

(21) Appl. No.: 19/542,417

(22) Filed: Feb. 17, 2026

Related U.S. Application Data
(63) Continuation of application No. PCT/CN2023/140981, filed on Dec. 22, 2023.

(30) Foreign Application Priority Data
Aug. 16, 2023 (CN) 202311028247.X

(51) Int. Cl. H02H 3/16; H02H 1/00; H02H 3/38; H02J 3/001; H02J 101/20

(52) U.S. Cl. CPC H02H 3/162; H02H 1/0038; H02H 1/0061; H02H 3/382; H02J 3/00125; H02J 2101/20

(57) ABSTRACT

The present application provides a new energy power station grounding protection system, a method, an electronic device and a storage medium. The system comprises a grounding protection apparatus, a grounding transformer neutral-point device, a first current transformer and a potential transformer. The potential transformer is configured to detect the voltage of a bus. The first current transformer is configured to detect the current of an outgoing line. The grounding protection apparatus is configured to acquire the voltage of the bus and the current of outgoing line, perform amplitude-phase comparison, acquire the closed/open state of a circuit breaker, determine whether a grid side connected to the outgoing line has a ground fault, and generate a corresponding on/off command to control the circuit breaker to perform a corresponding opening/closing operation according to the on/off command.

### CROSS-REFERENCE TO RELATED APPLICATIONS

The present application is a continuation application of International Application No. PCT/CN2023/140981, filed on Dec. 12, 2023, which claims the priority of Chinese Patent Application No. 202311028247.X, filed with the China National Intellectual Property Administration on Aug. 16, 2023, and entitled with “NEW ENERGY POWER STATION GROUNDING PROTECTION SYSTEM, METHOD, ELECTRONIC DEVICE AND STORAGE MEDIUM”. These applications are hereby incorporated by reference in their entireties.

### TECHNICAL FIELD

The present application relates to the technical field of new energy power system protection, and in particular, to a new energy power station grounding protection system, a method, an electronic device and a storage medium.

### BACKGROUND

With the development of new energy, measures for the new energy such as carbon emissions peak and carbon neutrality have gradually been implemented. For example, small-scale new energy power systems such as distributed wind power are connected to a distribution network nearby to implement local consumption, which saves transmission investment and loss.

Power system grounding modes are generally classified into effective grounding modes and non-effective grounding modes. The non-effective grounding modes can be further classified into a neutral point ungrounded mode, a neutral point low-resistance grounding mode, a neutral point high-resistance grounding mode, and a neutral point resonant grounding mode. The neutral point ungrounded mode is applicable to 35 kV distribution networks which are mainly composed of overhead lines and have a capacitive current less than 10 A during a single-phase ground fault. New energy power stations have numerous 35 kV cables and relatively large capacitive currents, and therefore, the low-resistance grounding mode is often adopted to meet the requirement for rapid fault clearance. However, when a new energy power station using the low-resistance grounding mode is directly connected to a 35 kV distribution network using the ungrounded mode, this leads to the problem of inconsistency in system neutral point grounding modes.

To solve this problem, the existing technology requires the addition of an isolating transformer with a voltage rating of 35/35 kV and a connection group of YNd, as well as accompanying secondary panels such as main transformer protection and main transformer measurement and control. This results in technical problems of high cost and increased consumption of manpower and device resources.

### SUMMARY

The present application provides a new energy power station grounding protection system, a method, an electronic device and a storage medium, which are used for solving the problem that in the prior art, the grounding modes of a new energy pow station and a distribution network are inconsistent, and devices such as an isolation transformer and a secondary panel need to be added, thereby increasing the consumption of manpower and device resources.

According to an embodiment of the first aspect of the present application, there is provided a new energy power station grounding protection system, which includes a grounding transformer neutral-point device, a first current transformer, a potential transformer and a grounding protection apparatus;
where a new energy power station includes a plurality of lines, and the plurality of lines include a bus, an outgoing line and a plurality of branches; the branches and the outgoing line are respectively connected to the bus, the bus is provided with the potential transformer, and the outgoing line is provided with the first current transformer; the potential transformer and the first current transformer are respectively connected to the grounding protection apparatus;
the potential transformer is configured to detect a voltage of the bus; the first current transformer is configured to detect a current of the outgoing line;
the plurality of branches include a grounding transformer branch provided with a grounding transformer and the grounding transformer neutral-point device; the grounding transformer neutral-point device includes a disconnector, a circuit breaker and a resistor which are connected in sequence; a high voltage side of the grounding transformer is connected to the bus, and a neutral point of the grounding transformer is grounded sequentially through the disconnector, the circuit breaker and the resistor;
the grounding protection apparatus is configured to: acquire the voltage of the bus and the current of the outgoing line; perform amplitude-phase comparison; acquire a closed/open state of the circuit breaker, and determine whether a grid side connected to the outgoing line has a ground fault to obtain a first determination result; generate a corresponding open/close command according to the first determination result and send the open/close command to the circuit breaker;
the circuit breaker performs a corresponding opening/closing operation according to the open/close command.

In an implementation, the grounding protection apparatus includes a processing module, and an analog input acquisition module, a binary input acquisition module and an output module which are respectively connected to the processing module;
where the analog input acquisition module includes a first interface of the analog input acquisition module and a tenth interface of the analog input acquisition module; the first interface of the analog input acquisition module is connected to the first current transformer; the tenth interface of the analog input acquisition module is connected to the potential transformer;
the binary input acquisition module includes a first interface of the binary input acquisition module, and the first interface of the binary input acquisition module is connected to the circuit breaker and configured to acquire the closed/open state of the circuit breaker;
the output module includes a fifth interface of the output module and a sixth interface of the output module, where the fifth interface of the output module is connected to a trip circuit of the circuit breaker and configured to output an open command; the sixth interface of the output module is connected to a close circuit of the circuit breaker to output a close command.

In an implementation, the processing module includes a first processing circuit and a second processing circuit connected in parallel, and the output module includes an output relay and a starting relay; where the output relay includes a first output relay, a second output relay, a third output relay, a fourth output relay, a fifth output relay and a sixth output relay; the fifth output relay is the fifth interface of the output module; the sixth output relay is the sixth interface of the output module;
the first processing circuit includes a first analog-to-digital conversion module and a first processor which are connected in sequence, and the second processing circuit includes a second analog-to-digital conversion module and a second processor which are connected in sequence;
the first processor is respectively connected to the first output relay, the second output relay, the third output relay, the fourth output relay, the fifth output relay and the sixth output relay; the second processor is connected to the starting relay;
the starting relay controls whether a positive power supply of the output relay is applied.

In an implementation, the plurality of branches further include a collector line and an SVG line; the collector line is provided with a second current transformer, and the SVG line is provided with a third current transformer; the grounding transformer branch is provided with a fourth current transformer arranged between the grounding transformer and the bus;
the second current transformer, the third current transformer and the fourth current transformer are respectively configured to detect a current of the collector line, a current of the SVG line, and a current of the grounding transformer branch;
the grounding protection apparatus performs threshold comparison on the voltage of the bus when the circuit breaker is in the open state, and if the voltage of the bus is greater than or equal to a preset threshold, the grounding protection apparatus performs calculation and amplitude-phase comparison on the voltage of the bus, the current of the outgoing line, the current of the collector line, the current of the SVG line, and the current of the grounding transformer branch to determine whether the bus has a ground fault and obtain a second determination result;
the grounding protection apparatus performs threshold comparison on the voltage of the bus when the circuit breaker is in the open state, and if the voltage of the bus is greater than or equal to the preset threshold, the grounding protection apparatus performs calculation and amplitude-phase comparison on the voltage of the bus and the current of the collector line to determine whether the collector line has a ground fault and obtain a third determination result;
the grounding protection apparatus performs threshold comparison on the voltage of the bus when the circuit breaker is in the open state, and if the voltage of the bus is greater than or equal to the preset threshold, the grounding protection apparatus performs calculation and amplitude-phase comparison on the voltage of the bus and the current of the SVG line to determine whether the SVG line has a ground fault and obtain a fourth determination result;
the grounding protection apparatus performs threshold comparison on the voltage of the bus when the circuit breaker is in the open state, and if the voltage of the bus is greater than or equal to the preset threshold, the grounding protection apparatus performs calculation and amplitude-phase comparison on the voltage of the bus and the current of the grounding transformer branch to determine whether the grounding transformer branch has a ground fault and obtain a fifth determination result.

In an implementation, the analog input acquisition module further includes a second interface of the analog input acquisition module, a third interface of the analog input acquisition module and a fourth interface of the analog input acquisition module, where:
the second interface of the analog input acquisition module is connected to the second current transformer;
the third interface of the analog input acquisition module is connected to the third current transformer;
the fourth interface of the analog input acquisition module is connected to the fourth current transformer.

In an implementation, the output module further includes a first interface of the output module, a second interface of the output module, a third interface of the output module and a fourth interface of the output module; the first interface of the output module is the first output relay; the second interface of the output module is the second output relay; the third interface of the output module is the third output relay; the fourth interface of the output module is the fourth output relay;
the outgoing line is also provided with a first circuit breaker located between the first current transformer and the bus; a trip circuit of the first circuit breaker is connected to the first interface of the output module;
the collector line is also provided with a second circuit breaker located between the second current transformer and the bus; a trip circuit of the second circuit breaker is connected to the second interface of the output module;
the SVG line is also provided with a third circuit breaker located between the third current transformer and the bus; a trip circuit of the third circuit breaker is connected to the third interface of the output module;
the grounding transformer branch is also provided with a fourth circuit breaker located between the fourth current transformer and the bus; a trip circuit of the fourth circuit breaker is connected to the fourth interface of the output module;
the processing module is configured to send a protection trip signal to the first circuit breaker, the second circuit breaker, the third circuit breaker, the fourth circuit breaker through the first interface of the output module, the second interface of the output module, the third interface of the output module and the fourth module of the output module respectively when the second determination result is that the bus has a ground fault;
the processing module is further configured to send a protection trip signal to the second circuit breaker through the second interface of the output module when the third determination result is that the collector line has a ground fault;
the processing module is further configured to send a protection trip signal to the third circuit breaker through the third interface of the output module when the fourth determination result is that the SVG line has a ground fault;
the processing module is further configured to send a protection trip signal to the fourth circuit breaker through the fourth interface of the output module when the fifth determination result is that the grounding transformer branch has a ground fault.

In an implementation, the new energy power station grounding protection system further includes a fifth current transformer arranged between the resistor and the ground, and a temperature control switch in a resistance chamber where the resistor is located;
the analog input acquisition module further includes a fifth interface of the analog input acquisition module, and the fifth interface of the analog input acquisition module is connected to the fifth current transformer;
the fifth current transformer is configured to detect a current of the resistor;
a second interface of the binary input acquisition module is connected to the temperature control switch and configured to acquire a state of the temperature control switch;
the processing module is configured to calculate an accumulated heat of the resistor according to the current of the resistor when the temperature control switch is in a closed state, and send an open command to the circuit breaker through the fifth interface of the output module when the accumulated heat of the resistor is greater than or equal to a preset heat threshold, and after a delay of a preset time period, send a protection trip signal to the fourth circuit breaker through the fourth interface of the output module.

According to an embodiment of the second aspect of the present application, there is provided a new energy power station grounding protection method, which is applied to a new energy power station grounding protection system, and the new energy power station grounding protection method includes:
detecting, through a potential transformer, a voltage of a bus, and sending the voltage of the bus to a grounding protection apparatus; detecting, through a first current transformer, a current of an outgoing line and sending the current of the outgoing line to the grounding protection apparatus;
acquiring, through the grounding protection apparatus, the voltage of the bus and the current of the outgoing line, performing amplitude-phase comparison, acquiring a closed/open state of a circuit breaker, and determining whether a grid side connected to the outgoing line has a ground fault to obtain a first determination result, and generating a corresponding open/close command according to the first determination result and sending the open/close command to the circuit breaker;
performing, by the circuit breaker, a corresponding opening/closing operation according to the open/close command.

In an implementation, the grounding protection apparatus includes a processing module, an analog input acquisition module, a binary input acquisition module and an output module, and the new energy power station grounding protection method further includes:
connecting the processing module to the analog input acquisition module, the binary input acquisition module and the output module respectively;
connecting a first interface of the analog input acquisition module to the first current transformer;
connecting a tenth interface of the analog input acquisition module to the potential transformer;
connecting a first interface of the binary input acquisition module to the circuit breaker to acquire the closed/open state of the circuit breaker;
connecting a fifth interface of the output module to a trip circuit of the circuit breaker to output a trip command;
connecting a sixth interface of the output module to a close circuit of the circuit breaker to output a close command.

In an implementation, the processing module includes a first processing circuit and a second processing circuit connected in parallel, and the output module includes an output relay and a starting relay; where the output relay includes a first output relay, a second output relay, a third output relay, a fourth output relay, a fifth output relay and a sixth output relay; the fifth output relay is the fifth interface of the output module; the sixth output relay is the sixth interface of the output module, and the new energy power station grounding protection method further includes:
sequentially connecting a first analog-to-digital conversion module and a first processor of the first processing circuit;
sequentially connecting a second analog-to-digital conversion module and a second processor of the second processing circuit;
connecting the first processor to the first output relay, the second output relay, the third output relay, the fourth output relay, the fifth output relay and the sixth output relay, respectively;
connecting the second processor to the starting relay;
controlling, through the starting relay, whether a positive power supply of the output relay is applied.

In an implementation, the plurality of branches further include a collector line and an SVG (Static Var Generator) line; the collector line is provided with a second current transformer, and the SVG line is provided with a third current transformer; the grounding transformer branch is provided with a fourth current transformer arranged between a grounding transformer and the bus, and the new energy power station grounding protection method further includes:
respectively detecting a current of the collector line, a current of the SVG line, and a current of the grounding transformer branch through the second current transformer, the third current transformer and the fourth current transformer;
when the circuit breaker is in the open state, the following operations are performed:
performing, through the grounding protection apparatus, threshold comparison on the voltage of the bus, and if the voltage of the bus is greater than or equal to a preset threshold, performing calculation and amplitude-phase comparison on the voltage of the bus, the current of the outgoing line, the current of the collector line, the current of the SVG line and the current of the grounding transformer branch to determine whether the bus has a ground fault and obtain a second determination result;
performing, through the grounding protection apparatus, threshold comparison on the voltage of the bus, and if the voltage of the bus is greater than or equal to the preset threshold, performing calculation and amplitude-phase comparison on the voltage of the bus and the current of the collector line to determine whether the collector line has a ground fault and obtain a third determination result;
performing, through the grounding protection apparatus, threshold comparison on the voltage of the bus, and if the voltage of the bus is greater than or equal to the preset threshold, performing calculation and amplitude-phase comparison on the voltage of the bus and the current of the SVG line to determine whether the SVG line has a ground fault and obtain a fourth determination result;
performing, through the grounding protection apparatus, threshold comparison on the voltage of the bus, and if the voltage of the bus is greater than or equal to the preset threshold, performing calculation and amplitude-phase comparison on the voltage of the bus and the current of the grounding transformer branch to determine whether the grounding transformer branch has a ground fault and obtain a fifth determination result.

In an implementation, the analog input acquisition module further includes a second interface of the analog input acquisition module, a third interface of the analog input acquisition module and a fourth interface of the analog input acquisition module, and the new energy power station grounding protection method further includes:
connecting the second interface of the analog input acquisition module to the second current transformer;
connecting the third interface of the analog input acquisition module to the third current transformer;
connecting the fourth interface of the analog input acquisition module to the fourth current transformer.

In an implementation, the output module further includes a first interface of the output module, a second interface of the output module, a third interface of the output module and a fourth interface of the output module; where the first interface of the output module is a first output relay; the second interface of the output module is a second output relay; the third interface of the output module is a third output relay; the fourth interface of the output module is a fourth output relay; the outgoing line is provided with a first circuit breaker located between the first current transformer and the bus; the collector line is provided with a second circuit breaker located between the second current transformer and the bus; the SVG line is provided with a third circuit breaker located between the third current transformer and the bus; the grounding transformer branch is provided with a fourth circuit breaker located between the fourth current transformer and the bus;
the new energy power station grounding protection method further includes:
connecting a trip circuit of the first circuit breaker to the first interface of the output module;
connecting a trip circuit of the second circuit breaker to the second interface of the output module;
connecting a trip circuit of the third circuit breaker to the third interface of the output module;
connecting a trip circuit of the fourth circuit breaker to the fourth interface of the output module;
when the second determination result is that the bus has a ground fault, sending, by the processing module, a protection trip signal to the first circuit breaker, the second circuit breaker, the third circuit breaker and the fourth circuit breaker through the first interface of the output module, the second interface of the output module, the third interface of the output module and the fourth module of the output module, respectively;
when the third determination result is that the collector line has a ground fault, sending, by the processing module, a protection trip signal to the second circuit breaker through the second interface of the output module;
when the fourth determination result is that the SVG line has a ground fault, sending, by the processing module, a protection trip signal to the third circuit breaker through the third interface of the output module;
when the fifth determination result is that the grounding transformer branch has a ground fault, sending, by the processing module, a protection trip signal to the fourth circuit breaker through the fourth interface of the output module.

In an implementation, the new energy power station grounding protection system further includes a fifth current transformer arranged between the resistor and the ground, and a temperature control switch in a resistance chamber where the resistor is located; the analog input acquisition module further includes a fifth interface of the analog input acquisition module; the new energy power station grounding protection method further includes:
connecting the fifth interface of the analog input acquisition module to the fifth current transformer;
detecting a current of the resistor through the fifth current transformer;
connecting the second interface of the binary input acquisition module to the temperature control switch to acquire a state of the temperature control switch;
when the temperature control switch is in a closed state, calculating, by the processing module, an accumulated heat of the resistor according to the current of the resistor, and when the accumulated heat of the resistor is greater than or equal to a preset heat threshold, sending an open command to the circuit breaker through the fifth interface of the output module, and after a delay of a preset time period, sending a protection trip signal to the fourth circuit breaker through the fourth interface of the output module.

According to an embodiment of the third aspect of the present application, an electronic device is provided, the electronic device includes at least one processor and a memory where computer-executable instructions are stored in the memory, and the at least one processor executes the computer-executable instructions stored in the memory, to cause the at least one processor to execute the new energy power station grounding protection method according to the embodiment of the above second aspect.

According to an embodiment of the fourth aspect of the present application, a computer-readable storage medium is provided, where the non-transitory computer-readable storage medium has computer-executable instructions stored therein, and the computer-executable instructions, when executed by a processor, are used to implement the new energy power station grounding protection method according to the embodiment of the above second aspect.

According to an embodiment of the fifth aspect of the present application, there is provided a computer program product, including a computer program, which, when executed by a processor, implements the new energy power station grounding protection method according to the embodiment of the above second aspect.

The present application provides a new energy power station grounding protection system, which includes a grounding transformer neutral-point device, a first current transformer, a potential transformer and a grounding protection apparatus; where, the new energy power station includes a plurality of lines, and the plurality of lines include a bus, an outgoing line and a plurality of branches. The branches and the outgoing line are respectively connected to the bus, the bus is provided with the potential transformer, and the outgoing line is provided with the first current transformer. The potential transformer and the first current transformer are respectively connected to the grounding protection apparatus. The potential transformer is configured to detect the voltage of the bus. The first current transformer is configured to detect the current of the outgoing line. The plurality of branches include a grounding transformer branch provided with a grounding transformer and the grounding transformer neutral-point device. The grounding transformer neutral-point device includes a disconnector, a circuit breaker and a resistor which are connected in sequence. The high voltage side of the grounding transformer is connected to the bus, and the neutral point of the grounding transformer is grounded sequentially through the disconnector, the circuit breaker and the resistor. The grounding protection apparatus is configured to acquire the voltage of the bus and the current of the outgoing line, perform amplitude-phase comparison, acquire the closed/open state of the circuit breaker, and determine whether a grid side connected to the outgoing line has a ground fault to obtain a first determination result, generate a corresponding open/close command according to the first determination result and send the open/close command to the circuit breaker. The circuit breaker performs a corresponding opening/closing operation according to the open/close command.

On the basis that the branches and the outgoing line are connected to the bus of the new energy power station, the present application can control, through the grounding protection apparatus, the circuit breaker of the grounding transformer neutral-point device to perform the opening/closing operation, thereby enabling control over whether the neutral point of the grounding transformer on the grounding transformer branch where the circuit breaker is located is grounded, i.e., achieving switching of the grounding protection system between a configuration of resistance grounding mode and a configuration of ungrounded mode. Therefore, the grounding protection system of the new energy power station provided by the present application can have the advantages of both the ungrounded mode and the low-resistance grounding mode, which not only meets the requirement that the distribution network operates for 1-2 hours with a ground fault in the ungrounded mode to ensure the continuity of power supply, but also meets the requirement that the new energy power station can quickly remove the ground fault. In addition, the system is a neutral adaptive grounding system in which the new energy power station is directly connected to the distribution network, and there is no need to add devices such as an isolation transformer and a secondary panel, which can save the consumption of manpower and device resources.

It should be understood that what is described in this section is not intended to identify key or important features of the embodiments of the present application, nor is it intended to limit the scope of the present application. Other features of the present application will be easily understood from the following description.

### BRIEF DESCRIPTION OF DRAWINGS

The accompanying drawings, which are incorporated in and constitute a part of this description, illustrate embodiments consistent with the present application and together with the description, serve to explain the principles of the present application.

FIG. 1 is a schematic structural diagram of a grounding protection system of a new energy power station provided by an embodiment of the present application.

FIG. 2 is a schematic structural diagram of another grounding protection system of a new energy power station provided by an embodiment of the present application.

FIG. 3 is a schematic structural diagram of a grounding protection apparatus provided by an embodiment of the present application.

FIG. 4 is a schematic diagram of results of another grounding protection system of a new energy power station provided by an embodiment of the present application.

FIG. 5 is a schematic diagram of a grounding transformer and a grounding transformer neutral-point device in a new energy power station provided by the embodiment of the present application.

FIG. 6 is a flow chart of a grounding protection method of a new energy power station provided by an embodiment of the present application.

FIG. 7 is a schematic structural diagram of an electronic device provided by an embodiment of the present application.

Through the above accompanying drawings, clear embodiments of the present application have been shown, which will be described in more detail later. These accompanying drawings and the descriptions are not intended to limit the scope of the concept of the present application in any way, but to explain the concept of the present application to those skilled in the art by referring to specific embodiments.

### DESCRIPTION OF EMBODIMENTS

Exemplary embodiments will now be described in detail, examples of which are illustrated in the accompanying drawings. When the following description refers to the accompanying drawings, unless otherwise indicated, the same numbers in different accompanying drawings indicate the same or similar elements. The implementations described in the following exemplary embodiments do not represent all implementations consistent with the present application.

Power system grounding modes are generally classified into effective grounding modes and non-effective grounding modes. The non-effective grounding modes can be further classified into a neutral point ungrounded mode, a neutral point low-resistance grounding mode, a neutral point high-resistance grounding mode, and a neutral point resonant grounding mode. The ungrounded mode is applicable to 35 kV distribution networks which are mainly composed of overhead lines and have a capacitive current less than 10 A during a single-phase ground fault. The instantaneous single-phase ground fault rate accounts for 60% to 70%, and it is desired that instantaneous ground faults do not trigger tripping. Its characteristics are: when the single-phase ground fault capacitive current is less than 10 A, the arc at the fault point can self-extinguish, and after arc extinction, the insulation at the fault point self-recovers; single-phase grounding does not disrupt system symmetry, allowing operation with fault for 1 to 2 hours, ensuring power supply continuity; in addition, this ungrounded mode has low communication interference and is suitable for places with numerous distribution points, wide coverage, and complex user profiles, thus greatly improving power supply reliability.

However, there are many 35 kV cables in the new energy power station, and the capacitive current is relatively large. Therefore, low-resistance grounding mode is often adopted to meet the requirement of quickly cutting off the ground fault.

However, when a new energy power station using the low-resistance grounding mode is directly connected to a 35 kV distribution network using the ungrounded mode, this leads to the issue of inconsistency in system neutral point grounding modes. To solve this problem, the existing technology requires the addition of an isolating transformer with a voltage rating of 35/35 kV and a connection group of YNd, as well as accompanying secondary panels for main transformer protection, main transformer measurement and control, etc. This results in technical problems of high cost and increased consumption of manpower and device resources.

In order to solve the above technical problems, the overall inventive concept of the present application is how to provide a new energy power station grounding protection system, which is applied to the field of new energy power system protection and is configured to combine the advantages of the ungrounded mode and the low-resistance grounding mode, and does not need to add an isolation transformer, a secondary panel and other device.

A technical solution of the present application and how the technical solution of the present application can solve the above technical problems will be described in detail with specific embodiments. The following specific embodiments can be combined with each other, and the same or similar concepts or processes may not be repeated in some embodiments. Embodiments of the present application will be described below with reference to the accompanying drawings.

### Embodiment 1

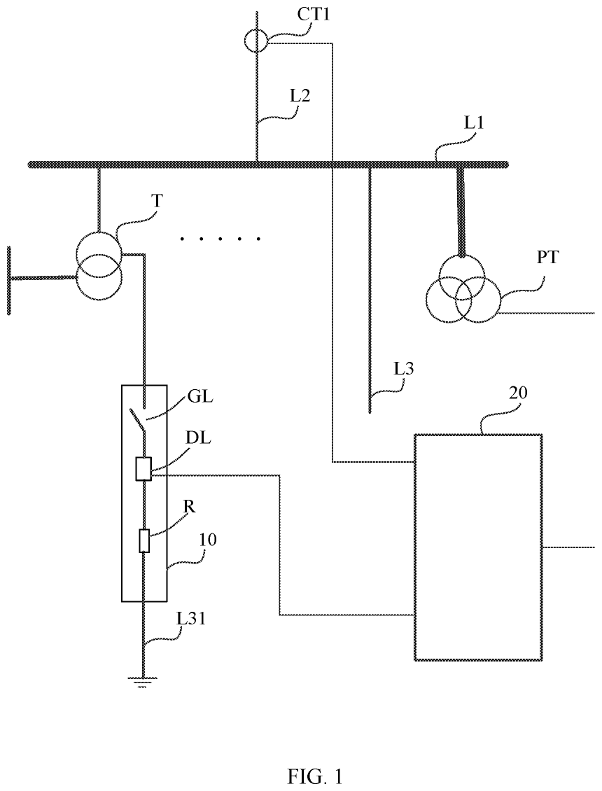

FIG. 1 is a schematic structural diagram of a grounding protection system of a new energy power station provided by an embodiment of the present application. As shown in FIG. 1, a new energy power station grounding protection system includes a grounding transformer neutral-point device 10, a first current transformer CT1, a potential transformer PT and a grounding protection apparatus 20.

The new energy power station includes several lines, including a bus L1, an outgoing line L2 and a plurality of branches L3. The branches L3 and the outgoing line L2 are respectively connected to the bus L1, and the bus L1 is provided with the potential transformer PT, and the outgoing line L2 is provided with the first current transformer CT1. The potential transformer PT and the first current transformer CT1 are respectively connected to the grounding protection apparatus 20.

In an embodiment of the present application, the bus L1 can refer to a 35 kV bus, one side of the outgoing line L2 is connected to the bus L1, and the other side of the outgoing line L2 is connected to a 35 kV distribution network or a distribution network with another voltage value. Embodiments of the present application does not specifically limit the specific voltage value of the connected distribution network.

The potential transformer PT is configured to detect the voltage of the bus L1. The first current transformer CT1 is configured to detect the current of the outgoing line L2.

It should be understood that the voltage of the bus L1 is an open-delta voltage of the 35 kV bus acquired by the potential transformer PT, or a zero-sequence voltage of the 35 kV bus, which can be denoted as 3U0. In addition, the outgoing line L2 is also called outgoing feeder, 35 kV outgoing feeder, etc. The first current transformer CT1 is a zero-sequence current transformer on the 35 kV outgoing feeder, and the detected current of the outgoing line L2 may be referred to as the zero-sequence current of the outgoing line, and can be denoted as 3I01.

The plurality of branches L3 include a grounding transformer branch L31 provided with a grounding transformer T and the grounding transformer neutral-point device 10. The grounding transformer neutral-point device 10 includes a disconnector GL, a circuit breaker DL and a resistor R which are connected in sequence. The high voltage side of the grounding transformer T is connected to the bus, and the neutral point of the grounding transformer T is grounded sequentially through the disconnector GL, the circuit breaker DL and the resistor R.

In an embodiment of the present application, the grounding transformer T may refer to a 35 kV grounding transformer with a connection group of ZNyn type, and this grounding transformer T also serves as a station service transformer, or is called a grounding transformer combined with station service transformer. In the ZNyn type, Z means that the primary winding has a zigzag connection, y means that the secondary winding has a star connection, and N and n mean the lead-out of the neutral line. In addition, the above-mentioned disconnector GL is also called a disconnecting switch. The above-mentioned circuit breaker DL can be understood as a neutral point circuit breaker of the grounding transformer, or as a 35 kV grounding transformer neutral point circuit breaker. The type of the circuit breaker DL can be a vacuum circuit breaker or other types of circuit breakers, which is not specifically limited in the embodiment of the present application. The resistance R is low-resistance, or is referred to as a 35 kV grounding transformer neutral point resistor, and its resistance value is not specifically limited in embodiments of the present application.

The grounding protection apparatus 20 is configured to acquire the voltage of the bus L1 and the current of the outgoing line L2, perform amplitude-phase comparison, acquire the open/close status of the circuit breaker DL, and determine whether a grid side connected to the outgoing line L2 has a ground fault to obtain a first determination result; generate a corresponding open/close command according to the first determination result; and send the open/close command to the circuit breaker DL.

In an embodiment of the present application, after acquiring the voltage of the bus L1, the grounding protection apparatus 20 can compare the voltage of the bus L1 with a threshold, where a preset threshold is Uset. The threshold comparison can be performed by one processor in the grounding protection apparatus 20, while the calculation and amplitude-phase comparison can be performed by another processor in the grounding protection apparatus 20. In addition, the structure of the grounding protection apparatus 20 is not specifically limited in embodiments of the present application.

The circuit breaker DL performs a corresponding opening/closing operation according to the open/close command.

Based on the 35 kV bus provided by the new energy power station, an embodiment of the present application forms a zero-sequence impedance network during a ground fault through a ZNyn-type grounding transformer. The grounding protection apparatus 20 controls the circuit breaker DL according to criteria, thereby switching the grounding protection system between a low-resistance grounding mode and an ungrounded mode, thus controlling the connection and disconnection of the zero-sequence impedance network during a ground fault.

In an embodiment of the present application, the types of ground faults include a ground fault on the grid side connected to the outgoing line L2 (or called external single-phase ground fault). The grounding protection apparatus 20 can determine whether this type of fault occurs according to criteria for the ground fault type of outgoing-line-L2-connected grid-side ground fault. The criteria for the ground fault type of outgoing-line-L2-connected grid-side ground fault is: 35 kV bus zero-sequence voltage

$$3 U 0 \geq Uset , - 180 ° \leq arg \frac{3 I 01}{3 U 0} \leq 0 ° , 3 I 01 \geq preset current value Iset .$$

In a specific example, the grounding protection apparatus 20 can first compare the 35 kV bus zero-sequence voltage 3U0 with a threshold, and then determine whether to apply the other two criteria according to the threshold comparison result. That is, if 3U0≤Uset, it can be known without applying the other two criteria, the first determination result is that: there is no ground fault on the grid side connected to the outgoing line L2, and there is no ground fault in the new energy power station (that is, there is no ground fault in the 35 kV system). If 3U0≥Uset, the grounding protection apparatus 20 can continue to detect and compare the phases of the 35 kV bus zero-sequence voltage and the outgoing line zero-sequence current 3I01 to obtain a phase comparison result

$$arg \frac{3 I 01}{3 U 0} .$$

If both the phase comparison result and the outgoing line zero-sequence current 3I01 meet the criteria for the ground fault type of outgoing-line-L2-connected grid-side ground fault, the first determination result is that: a ground fault occurs on the grid side connected to the outgoing line L2.

For the ground fault type of outgoing-line-L2-connected grid-side ground fault, the corresponding control strategy is: the grounding protection apparatus 20 sends an open command to the circuit breaker DL, so that the circuit breaker DL executes the open command to be in the open state (that is, trip the circuit breaker DL), and then the new energy power station grounding protection system is switched from the low-resistance grounding mode to the ungrounded mode, which can effectively prevent the neutral point resistance of the 35 kV grounding transformer from being damaged by overheating due to prolonged current flow. It should be understood that the open command is also called an open signal.

Different types of ground faults have different criteria, and different types of ground faults correspond to different control strategies. In Embodiment 1, the criteria and the control strategy for the ground fault type of outgoing-line-L2-connected grid-side ground fault are described in detail. For detailed descriptions of other types of ground faults, criteria and control strategies of types of ground faults, see the following Embodiment 3, which will not be repeated here.

In addition, an embodiment of the present application can determine whether the fault is restored according to criteria of fault recovery, and the criteria of fault recovery are that: the circuit breaker DL is in the open state and 3U0≤Uset. The corresponding control strategy of fault recovery is: after a delay of t, the grounding protection apparatus 20 sends a close command to the circuit breaker DL, so that the circuit breaker DL can execute the close command and switch from the open state to a closed state.

In an embodiment of the present application, the close command is also called a close signal.

An embodiment of the present application applies the grounding protection system of the new energy power station connected to the 35 kV distribution network. On the basis that the branches L3 and the outgoing line L2 are connected to the bus L1, the grounding protection apparatus 20 controls the circuit breaker DL in the grounding transformer neutral-point device 10 to perform the closing/opening operation, so as to control whether the neutral point of the grounding transformer T on the grounding transformer branch L31 where the circuit breaker DL is located is grounded or not, that is, to achieve switching of the grounding protection system of the new energy power station between a configurations of resistance grounding mode and a configuration of ungrounded mode. Therefore, the grounding protection system of the new energy power station provided by the present application can have the advantages of both the ungrounded mode and the low-resistance grounding mode, which not only meets the requirement that the distribution network operates for 1-2 hours with a ground fault in the ungrounded mode to ensure the continuity of power supply, but also meets the requirement that the new energy power station can quickly remove the ground fault. In addition, the system is a neutral adaptive grounding system in which the new energy power station is directly connected to the distribution network, and there is no need to add devices such as an isolation transformer and a secondary panel, which can save the capital investment of the isolation transformer and its associated protection, a measurement and control apparatus, as well as the consumption of manpower and device resources.

On the basis of the above embodiments, the technical solutions of the present application will be described in more detail with several specific embodiments.

### Embodiment 2

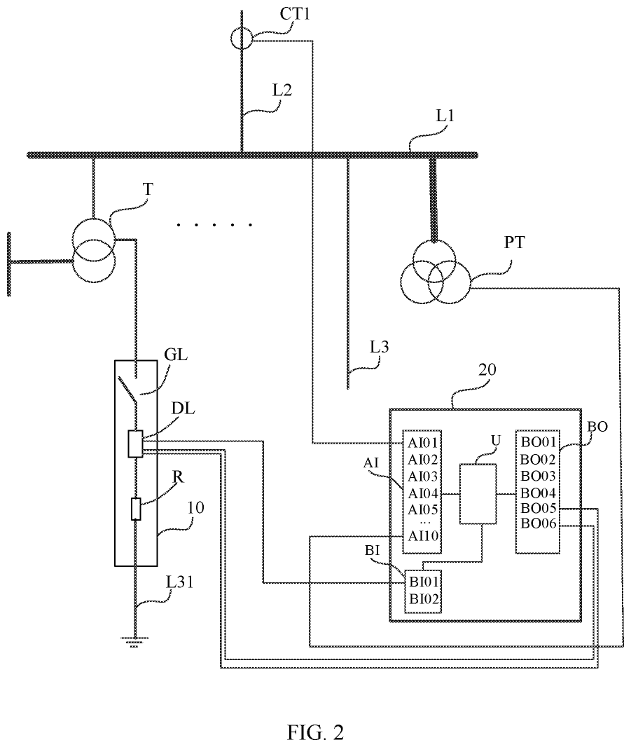

FIG. 2 is a schematic structural diagram of another grounding protection system of a new energy power station provided by an embodiment of the present application. The embodiment of the present application refines the structure of the grounding protection apparatus in the grounding protection system of the new energy power station.

As shown in FIG. 2, the grounding protection apparatus 20 includes a processing module U, and an analog input acquisition module AI, a binary input acquisition module BI and an output module BO which are respectively connected to the processing module U.

It should be understood that the analog input acquisition module AI could be called AI plug-in, the binary input acquisition module BI could be called BI plug-in, and the output module BO could be called BO plug-in or binary output module.

The analog input acquisition module AI includes a first interface AI01 of the analog input acquisition module and a tenth interface AI10 of the analog input acquisition module. The first interface AI01 of the analog input acquisition module is connected to the first current transformer CT1. The tenth interface AI10 of the analog input acquisition module is connected to the potential transformer PT.

In an embodiment of the present applications, the first interface AI01 of the analog input acquisition module is an analog input port of the grounding protection apparatus, and similarly, other interfaces of the analog input acquisition module AI are also analog input ports of the grounding protection apparatus. Thus, the analog input acquisition module AI is configured to acquire a voltage signal of the potential transformer PT and a current signal of the first current transformer CT1 and convert them into small voltage signals.

The binary input acquisition module BI includes a first interface BI01 of the binary input acquisition module, and the first interface BI01 of the binary input acquisition module is connected to the circuit breaker DL and configured to acquire the closed/open state of the circuit breaker DL. It can be seen that the binary input acquisition module BI is configured to acquire an open state of the circuit breaker DL.

In an embodiment of the present application, the first interface BI01 of the binary input acquisition module and a second interface BI02 of the binary input acquisition module are both binary input ports of the grounding protection apparatus.

The output module BO includes a fifth interface BO05 of the output module and a sixth interface BO06 of the output module, where the fifth interface BO05 of the output module is connected to the trip circuit of the circuit breaker DL for outputting the open command. The sixth interface BO06 of the output module is connected to the close circuit of the circuit breaker DL for outputting the close command.

In an embodiment of the present application, the fifth interface BO05 of the output module and the sixth interface BO06 of the output module are both binary output ports of the grounding protection apparatus, and similarly, other interfaces of the output module BO are also binary output ports of the grounding protection apparatus. The output module BO is configured to send the open command and the close command to the circuit breaker DL, and/or to send a trip command to at least one of the first circuit breaker DL1, the second circuit breaker DL2, the third circuit breaker DL3 or the fourth circuit breaker DL4.

Based on the above-mentioned structure, the grounding protection apparatus 20 of an embodiment of the present application can implement the control of the closed/open state of the circuit breaker DL, and can also implement the tripping of the first circuit breaker DL1, the second circuit breaker DL2, the third circuit breaker DL3 and the fourth circuit breaker DL4, so as to respond quickly when a fault occurs, and save the resource investment of adding an isolation transformer and its associated protection, a measurement and control device compared with the prior art.

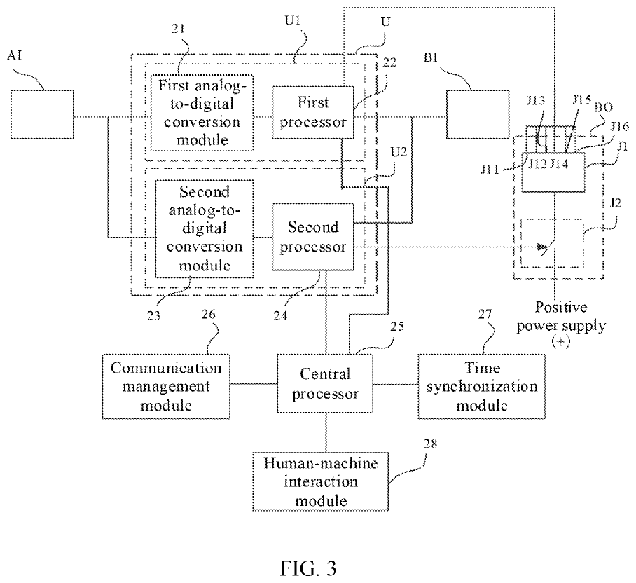

In a possible implementation, as shown in FIG. 3, the processing module U includes a first processing circuit U1 and a second processing circuit U2 connected in parallel, and the output module BO includes an output relay J1 and a starting relay J2. The output relay J1 includes a first output relay J11, a second output relay J12, a third output relay J13, a fourth output relay J14, a fifth output relay J15 and a sixth output relay J16. The fifth output relay J15 is the fifth interface BO05 of the output module. The sixth output relay J16 is the sixth interface BO06 of the output module.

It should be understood that the condition that the grounding protection apparatus 20 detects that the 35 kV bus zero-sequence voltage 3U0 exceeds a limit can be used as a criterion for the grounding protection apparatus to apply the positive power supply of the output relay J1 through the starting relay J2, so as to connect the output relay J1 to the positive power supply. The condition that the grounding protection apparatus 20 detects that the 35 kV bus zero-sequence voltage 3U0 exceeds the limit means that the 35 kV bus zero-sequence voltage 3U0 is greater than or equal to a preset threshold (that is, 3U0≥Uset).

The first processing circuit U1 includes a first analog-to-digital conversion module 21 and a first processor 22 connected in sequence, and the second processing circuit U2 includes a second analog-to-digital conversion module 23 and a second processor 24 connected in sequence.

It should be understood that both the first analog-to-digital conversion module 21 and the second analog-to-digital conversion module 23 may refer to an analog-to-digital conversion A/D module. The first processor 22 could be called a protection digital signal processor DSP module, and the second processor 24 could be called a starting DSP module.

The first analog-to-digital conversion module 21 converts the small voltage signal acquired by the analog input acquisition module AI into a digital signal through A/D sampling and holding, and transmits it to the first processor 22. Similarly, the second analog-to-digital conversion module 23 converts the small voltage signal acquired by the analog input acquisition module AI into a digital signal through A/D sampling and holding, and transmits it to the second processor 24.

The first processor 22 is respectively connected to the first output relay J11, the second output relay J12, the third output relay J13, the fourth output relay J14, the fifth output relay J15 and the sixth output relay J16.

In an embodiment of the present application, the grounding protection apparatus 20 further includes a power module. The power module is configured to provide the power needed by the grounding protection apparatus 20.

The second processor 24 is configured to perform a fault detection process, mainly for threshold comparison. When at least one ground fault of any type is detected (that is, all ground faults meet the following condition: 3U0≥Uset), the positive power supply of the output relay J1 is applied through the starting relay J2, so as to connect the output relay J1 to the positive power supply.

The first processor 22 is configured to execute a calculation process of protection logic, which is mainly configured to perform calculation and amplitude-phase comparison, determine a type of ground fault, generate a control signal including an executing subject and a command type according to the control strategy corresponding to the type of ground fault, and then drive, through the control signal, the output relay J1 to send an open/close command to the circuit breaker DL, and/or send a protection trip signal to at least one of the first circuit breaker DL1, the second circuit breaker DL2, the third circuit breaker DL3 or the fourth circuit breaker DL4, so that the executing subject can execute the corresponding command and complete the corresponding protection action. Different types of ground faults have different criteria, and different types of ground faults correspond to different control strategies. For detailed descriptions of all types of ground faults, criteria and control strategies for types of ground faults, see the above-mentioned Embodiment 1 and the following Embodiment 3, and they will not be repeated here.

In a possible implementation, as shown in FIG. 3, the grounding protection apparatus 20 further includes a central processor 25 connected to both the first processor 22 and the second processor 24, and a communication management module 26, a time synchronization module 27 and a human-machine interaction module 28 which are all connected to the central processor.

It should be understood that the central processor 25, which could be called central processing unit CPU module, is configured to implement sequence of event (SOE) recording, wave recording, printing, time synchronization, provide a human-machine interaction interface for the human-machine interaction module 28, and communicate with supervisory control and data acquisition (SCADA) system.

That is to say, the grounding protection apparatus 20 uploads, through a communication port, the operation information and the sequence of event records of the grounding protection apparatus 20 to the supervisory control and data acquisition SCADA system via a station control layer switch and a remote terminal unit, so that the background operators of the supervisory control and data acquisition SCADA system can monitor and control the new energy power station and the grounding protection system of the new energy power station.

It should be understood that the time synchronization module 27 may refer to a global positioning system GPS time synchronization module. The GPS time synchronization module is configured to control real-time synchronization of the data acquisition modules (namely, the above-mentioned analog input acquisition module AI and the binary input acquisition module BI), the protection DSP module and the starting DSP module, so that the calculation process of protection logic and the data acquired by the data acquisition modules are performed at the same time, while ensuring time synchronization of the grounding protection apparatus 20 with the supervisory control and data acquisition SCADA system and a dispatching system.

The human-machine interaction module 28 is configured to query and modify commands, and a user can obtain operating status of all devices in the new energy power station by inputting relevant settings into the human-machine interaction module 28.

In addition, an embodiment of the present application can also be provided with a protection information substation and a fault waveform recording apparatus which are respectively connected to the grounding protection apparatus 20. The grounding protection apparatus 20 uploads, through a communication port, the fault information (including the type of ground fault) corresponding to a protection action and the like to the protection information substation, and the protection information substation is configured to acquire fault information and upload the fault information to the dispatching system when the grounding protection system of the new energy power station performs the protection action. The grounding protection apparatus 20 outputs, through the binary output port, the binary quantity of the protection action to the fault waveform recording apparatus, so that the fault waveform recording apparatus can record waveforms when parameters exceed limits (for example, 3U0≥Uset, 3I01≥Iset, etc.), when the switch position changes (that is, the state of at least one circuit breaker changes), and when protection actions occur.

An embodiment of the present application proposes a new grounding protection system, i.e., a new energy power station grounding protection system, to address the problem of inconsistency in neutral point grounding modes caused by the connection of a new energy power station to a 35 kV distribution network. The system is a grounding protection system using an adaptive neutral point grounding mode, which combines the advantages of the low-resistance grounding mode and the ungrounded mode. It can not only meet the requirement of the 35 kV distribution network to operate with a ground fault for 1-2 hours to ensure power supply continuity, but also meet the requirement of the new energy power station to quickly remove the ground fault to ensure device safety.

### Embodiment 3

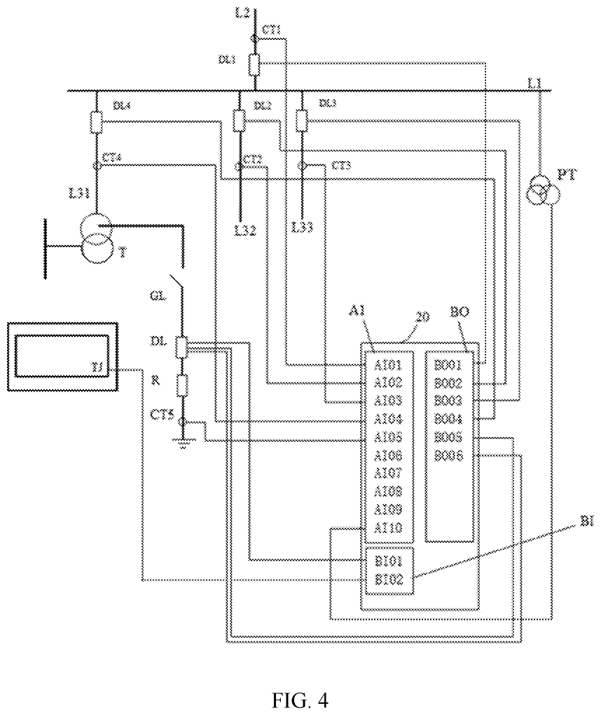

FIG. 4 is a schematic diagram of results of another grounding protection system of a new energy power station provided by an embodiment of the present application. As shown in FIG. 4, the plurality of branches L3 further include a collector line L32 and an SVG (Static Var Generator) line L33. The collector line L32 is provided with a second current transformer CT2, and the SVG line L33 is provided with a third current transformer CT3. The grounding transformer branch L31 is provided with a fourth current transformer CT4 between the grounding transformer T and the bus L1. The number of collector lines L32 can be one or multiple, so embodiments of the present application do not specifically limit the number thereof.

The second current transformer CT2, the third current transformer CT3 and the fourth current transformer CT4 are respectively configured to detect the current of the collector line L32, the current of the SVG line L33 and the current of the grounding transformer branch L31.

It should be understood that the second current transformer CT2 is a zero-sequence current transformer on the collector line L32, and the detected current of the collector line L32, which could be called 35 kV collector line zero-sequence current, can be denoted as 3I02. The third current transformer CT3 is a zero-sequence current transformer on the SVG line L33, and the detected current of the SVG line L33, which could be called 35 kV SVG zero-sequence current, can be denoted as 3I03. The fourth current transformer CT4 is a zero-sequence current transformer on the grounding transformer branch L31, and the detected current of the grounding transformer branch L31, which could be called 35 kV grounding transformer zero-sequence current, can be denoted as 3I04.

In an embodiment of the present application, the grounding protection apparatus 20 is also configured to: in combination with the outgoing line zero-sequence current 3I01, the 35 kV collector line zero-sequence current 3I02, the 35 kV SVG zero-sequence current 3I03 and the 35 kV grounding transformer zero-sequence current, etc., determine whether there are other types of ground fault such as a bus L1 ground fault, a grounding transformer branch L31 ground fault, a collector line L32 ground fault, an SVG line L33 ground fault, etc., when the 35 kV grounding transformer runs with the neutral point resistance ungrounded. The detailed analysis is as follows.

The grounding protection apparatus 20 performs threshold comparison on the voltage of the bus L1 when the circuit breaker DL is in the open state. If the voltage of the bus L1 is greater than or equal to a preset threshold, calculation and amplitude-phase comparison are performed on the voltage of the bus L1, the current of the outgoing line L2, the current of the collector line L32, the current of the SVG line L33 and the current of the grounding transformer branch L31 to determine whether the bus L1 has a ground fault, and a second determination result is obtained.

In an embodiment of the present application, the types of ground fault include the bus L1 ground fault. The grounding protection apparatus 20 can determine, according to criteria for the ground fault type of bus L1 ground fault, whether this type of fault occurs. The criteria for the ground fault type of bus L1 ground fault are:

$$3 U 0 \geq Uset , 0 ° \leq arg \frac{3 I 01}{3 U 0} \leq 180 ° , 0 ° \leq arg \frac{3 I 02}{3 U 0} \leq 180 ° , 0 ° \leq arg \frac{3 I 03}{3 U 0} \leq 180 ° , 0 ° \leq arg \frac{3 I 04}{3 U 0} \leq 180 °$$

and the circuit breaker DL being in the open state, 3I01≥preset current value Iset, 3I02≥preset current value Iset, 3I03≥preset current value Iset and 3I04≥preset current value Iset.

In a specific example, the grounding protection apparatus 20 can first compare the 35 kV bus zero-sequence voltage 3U0 with a threshold, and acquire the closed/open state of the circuit breaker DL, and then determine whether to apply the other eight criteria according to the threshold comparison result and the acquisition result of whether the circuit breaker DL is in the open state. That is, if the 3U0≤Uset or the circuit breaker DL is in the closed state, it can be known without applying the other eight criteria, the second determination result is that there is no ground fault on the bus L1. If the 3U0≥Uset and the circuit breaker DL is in the open state, the grounding protection apparatus 20 can be configured to continue to detect and compare the phases of the 35 kV bus zero-sequence voltage and the outgoing line zero-sequence current 3I01, the 35 kV collector line zero-sequence current 3I02, the 35 kV SVG zero-sequence current 3I03 and the 35 kV grounding transformer zero-sequence current 3I04 to obtain phase comparison results of

$$arg \frac{3 I 01}{3 U 0} , arg \frac{3 I 02}{3 U 0} , arg \frac{3 I 03}{3 U 0} and arg \frac{3 I 04}{3 U 0} ;$$

perform threshold comparison on the outgoing line zero-sequence current 3I01, the 35 kV collector line zero-sequence current 3I02, the 35 kV SVG zero-sequence current 3I03 and the 35 kV grounding transformer zero-sequence current 3I04. If all the phase comparison results and all the threshold comparison results meet the criteria for the ground fault type of bus L1 ground fault, the second determination result is that the bus L1 has a ground fault.

For the ground fault type of bus L1 ground fault, the corresponding control strategy is: after a time delay t, in the grounding protection apparatus 20, the first output relay J11, the second output relay J12, the third output relay J13 and the fourth output relay J14 all act, and send protection trip signals (simply referred to as trip commands) to the first circuit breaker DL1, the second circuit breaker DL2, the third circuit breaker DL3 and the fourth circuit breaker DL4 respectively, so that the first circuit breaker DL1, the second circuit breaker DL2, the third circuit breaker DL3 and the fourth circuit breaker DL4 all execute trip commands, and then switch to the open state (i.e. trip the first circuit breaker DL1, the second circuit breaker DL2, the third circuit breaker DL3 and the fourth circuit breaker DL4), and all branches in the 35 kV new energy power station are tripped to isolate the fault point.

In an embodiment of the present application, the bus L1 ground fault is one of the types of ground fault. The types of ground fault in embodiments of the present application include not only the outgoing-line-L2-connected grid-side fault in Embodiment 1 and the bus L1 ground fault here, but also ground faults of branch fault types such as a grounding transformer branch L31 ground fault, a collector line L32 ground fault, and an SVG line L33 ground fault.

The grounding protection apparatus 20 performs threshold comparison on the voltage of the bus L1 when the circuit breaker DL is in the open state. If the voltage of the bus L1 is greater than or equal to a preset threshold, calculation and amplitude-phase comparison are performed on the voltage of the bus L1 and the current of the collector line L32 to determine whether the collector line L32 has a ground fault, and a third determination result is obtained.

In an embodiment of the present application, the types of ground faults include branch faults, and the branch faults include a grounding transformer branch L31 ground fault, a collector line L32 ground fault and an SVG line L33 ground fault. For the collector line L32 ground fault, the grounding protection apparatus 20 can determine, according to criteria for the ground fault type of collector line L32 ground fault, whether this type of fault occurs. The criteria for the ground fault type of collector line L32 ground fault are:

$$3 U 0 \geq Uset , - 180 ° \leq arg \frac{3 I 02}{3 U 0} \leq 0 ° ,$$

the circuit breaker DL being in the open state, and 3I02≥preset current value Iset.

In a specific example, the grounding protection apparatus 20 can first compare the 35 kV bus zero-sequence voltage 3U0 with a threshold and acquire the closed/open state of the circuit breaker DL, and then determine whether to apply the other two criteria according to the threshold comparison result and the acquisition result of whether the circuit breaker DL is in the open state. That is, if the 3U0≤Uset or the circuit breaker DL is in the closed state, it can be known without apply the other two criteria, the third determination result is that the collector line L32 has no ground fault. If the 3U0≥Uset and the circuit breaker DL are in the open state, the grounding protection apparatus 20 can be configured to continue to detect and compare the phases of the 35 kV bus zero-sequence voltage and the 35 kV collector line zero-sequence current 3I02 to obtain a phase comparison result

$$arg \frac{3 I 02}{3 U 0} ,$$

and perform threshold comparison on the 35 kV collector line zero-sequence current 3I02. If both the phase comparison result and the threshold comparison result both meet the criteria for the ground fault type of collector line L32 ground fault, the third determination result is that the collector line L32 has a ground fault.

For the ground fault type of collector line L32 ground fault, the corresponding control strategy is that: after a time delay t, in the grounding protection apparatus 20, the second output relay J12 acts, and sends a protection trip signal to the second circuit breaker DL2, so that the second circuit breaker DL2 executes a trip command, and then switches to the open state (that is, trip the second circuit breaker DL2), and the fault line is tripped to isolate the fault point.

The grounding protection apparatus 20 performs threshold comparison on the voltage of the bus L1 when the circuit breaker DL is in the open state. If the voltage of the bus L1 is greater than or equal to a preset threshold, calculation and amplitude-phase comparison are performed on the voltage of the bus L1 and the current of the SVG line L33 to determine whether the SVG line L33 has a ground fault, and a fourth determination result is obtained.

In an embodiment of the present application, the types of ground faults include branch faults, and the branch faults include a grounding transformer branch L31 ground fault, a collector line L32 ground fault and an SVG line L33 ground fault. For the SVG line L33 ground fault, the grounding protection apparatus 20 can determine, according to criteria for the ground fault type of SVG line L33 ground fault, whether this type of fault occurs. The criteria for the ground fault type of SVG line L33 ground fault are:

$$3 U 0 \geq Uset , - 180 ° \leq arg \frac{3 I 03}{3 U 0} \leq 0 ° ,$$

the circuit breaker DL being in the open state, and 3I03≥preset current value Iset.

In a specific example, the grounding protection apparatus 20 can first compare the 35 kV bus zero-sequence voltage 3U0 with a threshold and acquire the closed/open state of the circuit breaker DL, and then determine whether to apply the other two criteria according to the threshold comparison result and the acquisition result of whether the circuit breaker DL is in the open state. That is, if the 3U0≤Uset or the circuit breaker DL is in the closed state, it can be known without applying the other two criteria, the fourth determination result is that the SVG line L33 has no ground fault. If the 3U0≥Uset and the circuit breaker DL are in the open state, the grounding protection apparatus 20 can be configured to continue to detect and compare the phases of the 35 kV bus zero-sequence voltage and the 35 kV SVG zero-sequence current 3I03 to obtain a phase comparison result

$$arg \frac{3 I 03}{3 U 0} ,$$

and perform threshold comparison on the 35 kV SVG zero-sequence current 3I03. If both the phase comparison result and the threshold comparison result meet the criteria for the ground fault type of SVG line L33 ground fault, the fourth determination result is that SVG line L33 has a ground fault.

For the ground fault type of SVG line L33 ground fault, the corresponding control strategy is that after a time delay t, in the grounding protection apparatus 20, the third output relay J13 acts, and sends a protection trip signal to the third circuit breaker DL3, so that the third circuit breaker DL3 executes a trip command, and then switches to the open state (that is, trip the third circuit breaker DL3), and the fault line is tripped to isolate the fault point.

The grounding protection apparatus 20 performs threshold comparison on the voltage of the bus L1 when the circuit breaker DL is in the open state. If the voltage of the bus L1 is greater than or equal to a preset threshold, calculation and amplitude-phase comparison are performed on the voltage of the bus L1 and the current of the grounding transformer branch L31 to determine whether the grounding transformer branch L31 has a ground fault, and a fifth determination result is obtained.

In an embodiment of the present application, the types of ground faults include branch faults, and the branch faults include a grounding transformer branch L31 ground fault, a collector line L32 ground fault and a SVG line L33 ground fault. For the grounding transformer branch L31 ground fault, the grounding protection apparatus 20 can determine, according to criteria for the ground fault type of grounding transformer branch L31 ground fault, whether this type of fault occurs. The criteria for the ground fault type of grounding transformer branch L31 ground fault are:

$$3 U 0 \geq Uset , - 180 ° \leq arg \frac{3 I 04}{3 U 0} \leq 0 ° ,$$

the circuit breaker DL being in the open state, and 3I04≥preset current value Iset.

In a specific example, the grounding protection apparatus 20 can first compare the 35 kV bus zero-sequence voltage 3U0 with a threshold and acquire the closed/open state of the circuit breaker DL, and then determine whether to apply the other two criteria according to the threshold comparison result and the acquisition result of whether the circuit breaker DL is in the open state. That is, if the 3U0≤Uset or the circuit breaker DL is in the closed state, it can be known without applying the other two criteria, the fifth determination result is that there is no ground fault in the grounding transformer branch L31. If the 3U0≥Uset and the circuit breaker DL are in the open state, the grounding protection apparatus 20 can be configured to continue to detect and compare the phases of the 35 kV bus zero-sequence voltage and the 3 KV grounding transformer zero-sequence current 3I04 to obtain the phase comparison result

$$arg \frac{3 I 04}{3 U 0} ,$$

and perform threshold comparison on the 35 kV grounding transformer zero-sequence current 3I04. If both the phase comparison result and the threshold comparison result meet the criteria for the ground fault type of grounding transformer branch L31 ground fault, the fifth determination result is that the grounding transformer branch L31 has a ground fault.

For the ground fault type of grounding transformer branch L31, the corresponding control strategy is: after a time delay t, in the grounding protection apparatus 20, the fourth output relay J14 acts, and sends a protection trip signal to the fourth circuit breaker DL4, so that the fourth circuit breaker DL4 executes a trip command, and then switches to the open state (that is, trip the fourth circuit breaker DL4), and the fault line is tripped to isolate the fault point.

Embodiments of the present application can accurately and effectively identify a faulty branch when a ground fault occurs on any branch, thereby improving system safety.

In a possible implementation, as shown in FIG. 4, the analog input acquisition module AI further includes a second interface AI02 of the analog input acquisition module, a third interface AI03 of the analog input acquisition module and a fourth interface AI04 of the analog input acquisition module. The second interface AI02 of the analog input acquisition module is connected to the second current transformer CT2. The third interface AI03 of the analog input acquisition module is connected to the third current transformer CT3. The fourth interface AI04 of the analog input acquisition module is connected to the fourth current transformer CT4.

The analog input acquisition module AI is not only configured to acquire the voltage signal of the potential transformer PT and the current signal of the first current transformer CT1 and convert them into corresponding small voltage signals, but also configured to acquire the current signals of the second current transformer CT2, the third current transformer CT3 and the fourth current transformer CT4 and convert them into corresponding small voltage signals.

In embodiments of the present application, the analog input acquisition module AI provides a corresponding interface for each current transformer and potential transformer, so as to acquire current and voltage, which can provide data support for accurately identifying fault types and fault lines.

In a possible implementation, as can be seen from FIG. 1 to FIG. 4, the output module BO further includes a first interface BO01 of the output module, a second interface BO02 of the output module, a third interface BO03 of the output module and a fourth interface BO04 of the output module. The first interface BO01 of the output module is the first output relay J11, the second interface BO02 of the output module is the second output relay J12, the third interface BO03 of the output module is the third output relay J13, and the fourth interface BO04 of the output module is the fourth output relay J14.

The outgoing line L2 is also provided with the first circuit breaker DL1 located between the first current transformer CT1 and the bus L1. The trip circuit of the first circuit breaker DL1 is connected to the first interface BO01 of the output module.

The collector line L32 is also provided with the second circuit breaker DL2 located between the second current transformer CT2 and the bus L1. The trip circuit of the second circuit breaker DL2 is connected to the second interface BO02 of the output module.

The SVG line L33 is also provided with the third circuit breaker DL3 located between the third current transformer CT3 and the bus L1. The trip circuit of the third circuit breaker DL3 is connected to the third interface BO03 of the output module.

The grounding transformer branch L31 is also provided with the fourth circuit breaker DL4 located between the fourth current transformer CT4 and the bus L1. The trip circuit of the fourth circuit breaker DL4 is connected to the fourth interface BO04 of the output module.

The processing module U is configured to send protection trip signals to the first circuit breaker DL1, the second circuit breaker DL2, the third circuit breaker DL3 and the fourth circuit breaker DL4 through the first interface BO01 of the output module, the second interface BO02 of the output module, the third interface BO03 of the output module and the fourth module BO04 of the output module respectively when the second determination result is that the bus L1 has a ground fault. This part of technical solution provides a detailed description of the control strategy for the ground fault type of bus L1 ground fault.

The processing module U is also configured to send a protection trip signal to the second circuit breaker DL2 through the second interface BO02 of the output module when the third determination result is that the collector line L32 has a ground fault.

The protection trip signal is also called an open command. This part of technical scheme provides a detailed description of the control strategy for the ground fault type of collector line L32 ground fault.

The processing module U is also configured to send a protection trip signal to the third circuit breaker DL3 through the third interface BO03 of the output module when the fourth determination result is that the SVG line L33 has a ground fault. This part of technical scheme provides a detailed description of the control strategy for the ground fault type of SVG line L33 ground fault.

The processing module U is also configured to send a protection trip signal to the fourth circuit breaker DL4 through the fourth interface BO04 of the output module when the fifth determination result is that the grounding transformer branch L31 has a ground fault. This part of technical scheme provides a detailed description of the control strategy for the ground fault type of grounding transformer branch L31 ground fault.

It can be seen that the output module BO is not only configured to send open and close commands to the circuit breaker DL, but also configured to send protection trip signals to at least one of the first circuit breaker DL1, the second circuit breaker DL2, the third circuit breaker DL3 or the fourth circuit breaker DL4.

In embodiments of the present application, the output module BO provides a corresponding interface for each circuit breaker, so as to realize the accurate implementation of a control strategy, which can provide support for isolating fault points and ensuring system safety.

In a possible implementation, as shown in FIG. 4, the system further includes a fifth current transformer CT5 arranged between the resistor R and the ground, and a temperature control switch TJ in a resistance chamber where the resistor R is located.

It should be understood that, the binary quantity includes the input quantity and the output quantity, which are digital signals, and there are only two states, namely, 0 and 1, which respectively indicate the opening and closing of relay contacts; therefore, the temperature control switch TJ can be understood as the overtemperature contact of a temperature controller in a resistance cabinet of the 35 kV grounding transformer, which switches from the open state to the closed state after exceeding a preset temperature threshold.

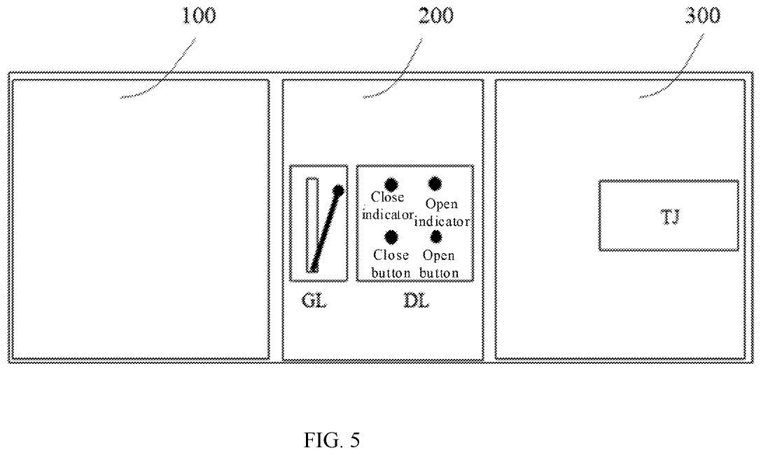

As shown in FIG. 5, a resistance chamber 300, a transformer chamber 100 and an operation apparatus chamber 200 constitute a 35 kV grounding transformer resistance cabinet (referred to as grounding transformer resistance cabinet for short). The resistor R, the fifth current transformer CT5 and the temperature control switch TJ are installed in the resistance chamber 300. The temperature control switch TJ can be installed on the cabinet of the resistance chamber 300. A grounding transformer T is installed in the transformer chamber 100. In addition, the disconnector GL and the circuit breaker DL mentioned above are installed in the operation apparatus chamber 200.

A close indicator light and an open indicator light of the circuit breaker DL are also installed in the operation apparatus chamber 200, which are used for close indication and open indication respectively. A close button and an open button of the circuit breaker DL are also installed in the operation apparatus chamber 200, which is convenient for users to operate manually. An operating handle of the disconnector GL is also installed in the operation apparatus chamber 200 for the opening and closing operation of the disconnector GL. It should be understood that the operation apparatus chamber 200 is also called a switch room.

It should be noted that in addition to the corresponding branch integrated protection, measurement and control apparatus on the grounding transformer branch L31, there are corresponding branch integrated protection, measurement and control apparatuses on the collector line L32 and the SVG line L33.

The analog input acquisition module AI further includes a fifth interface AI05 of the analog input acquisition module, and the fifth interface AI05 of the analog input acquisition module is connected to the fifth current transformer CT5.

The fifth current transformer CT5 is configured to detect the current of the resistor R. The fifth current transformer CT5 is the current transformer at the neutral point of the grounding transformer, and the detected current at the neutral point of the grounding transformer can be denoted as 3I05.

The second interface BI02 of the binary input acquisition module is connected to the temperature control switch TJ for acquiring the state of the temperature control switch TJ. It can be seen that the binary input acquisition module BI is not only configured to acquire the open state of the circuit breaker DL, but also configured to acquire a binary quantity signal of the temperature control switch TJ.

The processing module U is configured to calculate the accumulated heat (3I05)²t of the resistor R according to the current of the resistor R when the temperature control switch TJ is in the closed state. When the accumulated heat (3I05)²t of the resistor R is greater than or equal to a preset heat threshold Qₛₑₜ, an open command is sent to the circuit breaker DL through the fifth interface BO05 of the output module, and after a delay of a preset time period, a protection trip signal is sent to the fourth circuit breaker DL4 through the fourth interface BO04 of the output module.

In embodiments of the present application, in addition to the ground fault types, such as the outgoing line L2 fault, the bus L1 ground fault, the grounding transformer branch L31 ground fault, the collector line L32 ground fault, the SVG line L33 ground fault, an execution failure (i.e., a failure caused by a circuit breaker DL refusing to operate) is also provided. For the execution failure, the criteria are: 3U0≥Uset and (3I05)²t≥Qₛₑₜ, and the temperature control switch TJ is in the closed state. The control strategy thereof is as follows: the fifth output relay J15 acts and sends an open command to the circuit breaker DL again, and after a time delay t, the sixth output relay J16 acts, and sends a protection trip signal to the fourth circuit breaker DL4.

According to embodiments of the present application, the grounding protection system can be switched between a configuration of resistance grounding mode and a configuration of ungrounded mode in various situations. Therefore, the grounding protection system of the new energy power station provided by the present application can have the advantages of both the ungrounded mode and the low-resistance grounding mode, which not only meets the requirement that the distribution network operates for 1-2 hours with a ground fault in the ungrounded mode to ensure the continuity of power supply, but also meets the requirement that the new energy power station can quickly remove the ground fault.

As can be seen from FIG. 4, the embodiment of the present application provides the grounding protection system of the new energy power station connected to the 35 kV distribution network, where the grounding transformer T is connected to the 35 kV bus provided by the new energy power station, and the neutral point of the grounding transformer T is grounded sequentially through the disconnector GL, the circuit breaker DL and the resistor R, and a fifth current transformer CT5 is installed at the grounding end of the resistor R. The 35 kV bus zero-sequence voltage 3U0 detected by the potential transformer PT on the 35 kV bus is provided to the tenth interface AI10 of the analog input acquisition module, the outgoing line zero-sequence current 3I01 is provided to the first interface AI01 of the analog input acquisition module, and the 35 kV collector line zero-sequence current 3I02 is provided to the second interface AI02 of the analog input acquisition module, the 35 kV SVG zero-sequence current 3I03 is provided to the third interface AI03 of the analog input acquisition module, the 35 kV grounding transformer zero-sequence current 3I04 is provided to the fourth interface AI04 of the analog input acquisition module, and the grounding transformer neutral point current 3I05 is provided to the fifth interface AI05 of the analog input acquisition module. The trip circuit of the first circuit breaker DL1 located on the outgoing line L2 is connected to the first interface BO01 of the output module, the trip circuit of the second circuit breaker DL2 located on the collector line L32 is connected to the second interface BO02 of the output module, and the trip circuit of the third circuit breaker DL3 located on the SVG line L33 is connected to the third interface BO03 of the output module, the trip circuit of the fourth circuit breaker DL4 located on the grounding transformer branch L31 is connected to the fourth interface BO04 of the output module, the trip circuit of the circuit breaker DL is connected to the fifth interface BO05 of the output module, the close circuit of the circuit breaker DL is connected to the sixth interface BO06 of the output module, the open circuit of the circuit breaker DL is connected to the first interface BI01 of the binary input acquisition module, and the temperature control switch TJ is connected to the second interface BI02 of the binary input acquisition module.

### Embodiment 4

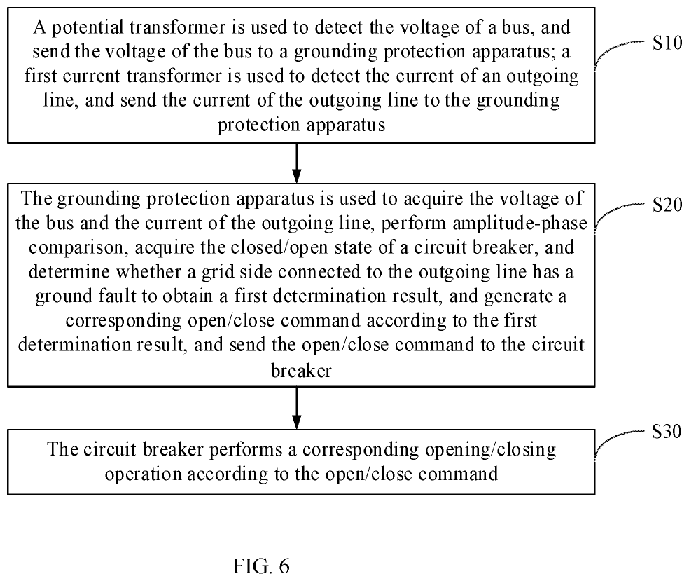

FIG. 6 is a flow chart of a grounding protection method of a new energy power station provided by an embodiment of the present application. As shown in FIG. 6, the method of this embodiment is applied to the grounding protection system of the new energy power station provided by any one of embodiment 1 to embodiment 3, and the method of this embodiment includes the following steps.
S10: detecting, through a potential transformer, the voltage of a bus, and sending the voltage of the bus to a grounding protection apparatus; detecting, through a first current transformer, the current of an outgoing line, and sending the current of the outgoing line to the grounding protection apparatus.
S20: acquiring, through the grounding protection apparatus, the voltage of the bus and the current of the outgoing line, performing amplitude-phase comparison, acquiring the closed/open state of a circuit breaker, and determining whether a grid side connected to the outgoing line has a ground fault to obtain a first determination result, and generating a corresponding open/close command according to the first determination result, and sending the open/close command to the circuit breaker.
S30: performing, by the circuit breaker, a corresponding opening/closing operation according to the open/close command.

The embodiments of the present application analyze the method as follows according to scenario changes:
(1) During normal operation, 35 kV distribution network operates with its neutral point ungrounded, while the new energy power station connected to the 35 kV distribution network operates with its neutral point grounded through a low resistance.
(2) If an internal single-phase ground fault occurs in the new energy power station during normal operation (external refers to the 35 kV distribution network connected to the outgoing lines), then since the neutral point of the new energy power station is grounded through a low resistance, its zero-sequence current is relatively large.

When the fault point is on the outgoing line, the differential protection of the outgoing line acts to remove the fault. When the fault point is on the 35 kV bus in the new energy power station, the differential protection of the 35 kV bus acts to remove the fault. When the fault point occurs on the collector line, the SVG line or the grounding transformer branch in the new energy power station, a corresponding branch integrated protection, measurement and control apparatus perform an action to remove the faults. In addition, the grounding transformer zero-sequence protection can serve as a remote backup protection for ground faults on the collector line and the SVG line.
(3) If an external single-phase ground fault occurs while the new energy power station is in normal operation, the zero-sequence current is large since the new energy power station operates with its neutral point grounded through a low resistance, which is convenient for accurately selecting the fault line in the 35 kV distribution network. By detecting and comparing the phases of the 35 kV bus zero-sequence voltage 3U0 and the outgoing line zero-sequence current 3I01, the grounding protection apparatus sends a trip signal to the circuit breaker DL to trip the circuit breaker DL, and the new energy power station is switched from the low-resistance grounding mode to the ungrounded mode.

In order to prevent the circuit breaker DL from refusing to operate and the neutral point resistance of the 35 kV grounding transformer from being damaged due to overheating caused by prolonged current flow, the grounding protection apparatus detects the closed state of the temperature control switch TJ and the current 3I05 of the neutral point of the grounding transformer, and calculates the heat accumulation. If the circuit breaker DL refuses to operate, the grounding protection apparatus instantaneously trips the circuit breaker DL again, and after a time delay t, acts on the fourth circuit breaker DL4, so as to make the fourth circuit breaker DL4 trip, thereby providing dual protection for the operational safety of the new energy power station in the low-resistance grounding mode.
(4) While an external single-phase ground fault occurs, if an internal single-phase ground fault occurs simultaneously on the same phase in the new energy power station, the fault current is a system capacitive current because the new energy power station operates with its neutral point ungrounded. The fault current is shunted at the external and internal fault grounding points. By performing amplitude and phase comparison on the zero-sequence voltage and zero-sequence current of the internal fault branch, the comparison result can be determined to meet the action conditions, and the grounding protection apparatus acts to send a protection trip signal corresponding to the fault branch to trip the fault branch and isolate the fault point. For example, when the internal fault point of the single-phase ground fault on the same phase is on the 35 kV bus, the collector line, the SVG line or the grounding transformer branch of the new energy power station, the grounding protection apparatus acts to remove the fault.

While an external single-phase ground fault occurs, if an internal single-phase ground fault occurs simultaneously on a different phase in the new energy power station, it is equivalent to two-phase short-circuit grounding. The corresponding branch integrated protection, measurement and control apparatus can perform overcurrent protection to remove the fault, and the grounding protection apparatus, acting as a backup protection device, can also act to remove the fault.
(5) If, after an external single-phase ground fault occurs, the new energy power station recovers after a period of time, and at this time the 35 kV bus zero-sequence voltage 3U0 returns from exceeding a limit, then the grounding protection apparatus, after a time delay t, sends a close command to the circuit breaker DL, so that the new energy power station can be switched from the ungrounded mode to the low-resistance grounding mode.

In summary, the embodiments of the present application perform external and internal fault discrimination through amplitude and phase comparison of zero-sequence voltage and zero-sequence current. The occurrence/elimination of an external fault is determined based on the 35 kV bus zero-sequence voltage 3U0 acting as exceeding a limit or returning from exceeding the limit, and the opening/closing operation of the circuit breaker DL is performed, thereby realizing automatic switching of the neutral point grounding mode of the new energy power station. When an internal fault occurs during an external fault, the embodiment can perform amplitude and phase comparison of zero-sequence voltage and zero-sequence current, thereby improving the accuracy of line selection and tripping. The beneficial effects: (1) the embodiments can combine the advantages of the ungrounded mode and the low-resistance grounding mode to construct a neutral point adaptive grounding system for the new energy power station connected to the distribution network; (2) the embodiments save resource investment in adding isolation transformers and its associated protection, measurement and control devices.

The implementation principle and technical effect of the new energy power station grounding protection method provided by this embodiment are similar to those of the new energy power station grounding protection system provided by the above system embodiment, and will not be repeated here.

It should be noted that the user information and data involved in the present application (including but not limited to data used for analysis, stored data, displayed data, etc.) are all information and data authorized by users or fully authorized by all parties, and the acquisition, use and processing of relevant data need to comply with relevant laws, regulations and standards of relevant countries and regions, and corresponding operation portals are provided for users to choose authorization or rejection. That is to say, in the technical solutions of the present application, the acquisition, storage, use, processing, transmission, provision and disclosure of the involved users' personal information are all in compliance with the provisions of relevant laws and regulations, and do not violate public order and good customs.

According to embodiments of the present application, the present application also provides an electronic device and a readable storage medium.

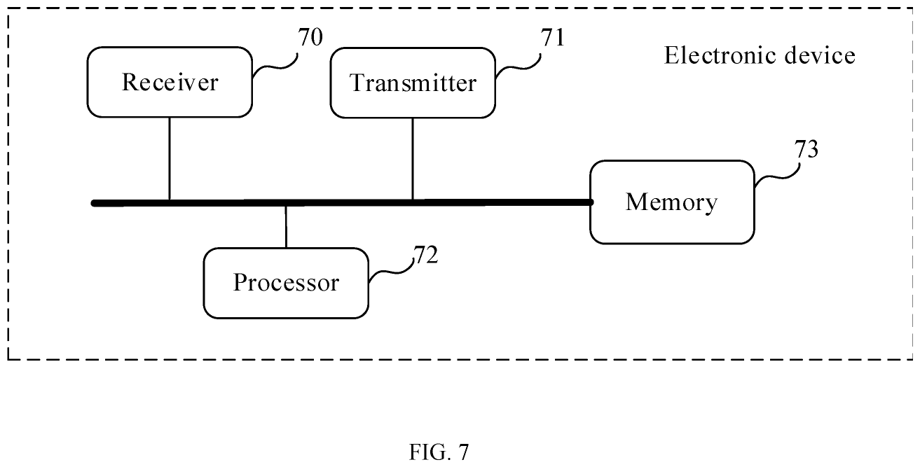

FIG. 7 is a schematic structural diagram of an electronic device provided by an embodiment of the present application. The electronic device includes a receiver 70, a transmitter 71, at least one processor 72 and a memory 73, and the electronic device formed by the above components can be configured to implement the above specific embodiments of the present application, which will not be described in detail here.

An embodiment of the present application also provides a computer-readable storage medium, where computer-executable instructions are stored in the computer-readable storage medium, and when a processor executes the computer-executable instructions, steps in the method in the above embodiments are implemented.

An embodiment of the present application also provides a computer program product, including a computer program, which, when executed by a processor, implements steps in the method in the above embodiments.

Various implementations of the system and technology described above in the present application can be implemented in a digital electronic circuit system, an integrated circuit system, a field programmable gate array (FPGA), an application specific integrated circuit (ASIC), an application specific standard product (ASSP), a system-on-chip (SOC) system, a complex programmable logic device (CPLD), computer hardware, firmware, software, and/or a combination thereof. These various implementations may include being implemented in one or more computer programs that can be executed and/or interpreted on a programmable system including at least one programmable processor, which may be a special-purpose or general-purpose programmable processor and can receive data and commands from a storage system, at least one input apparatus, and at least one output apparatus, and transmit data and commands to the storage system, the at least one input apparatus, and the at least one output apparatus.

It should be understood that steps can be reordered, added or deleted using the various forms of flows shown above. For example, the steps described in the disclosure of the present application can be executed in parallel, sequentially or in a different order, so long as the desired results of the technical solution disclosed in the present application can be achieved, and there is no restriction here.

The above specific implementations do not limit the protection scope of the present application. It should be understood by those skilled in the art that various modifications, combinations, sub combinations and substitutions can be made according to design requirements and other factors. Any modification, equivalent substitution and improvement within the principles of the present application should be included in the protection scope of the present application.

1. A new energy power station grounding protection system, comprising a grounding transformer neutral-point device, a first current transformer, a potential transformer and a grounding protection apparatus;
wherein a new energy power station comprises a plurality of lines, and the plurality of lines comprise a bus, an outgoing line and a plurality of branches; the branches and the outgoing line are respectively connected to the bus, the bus is provided with the potential transformer, and the outgoing line is provided with the first current transformer; the potential transformer and the first current transformer are respectively connected to the grounding protection apparatus;
wherein the potential transformer is configured to detect a voltage of the bus; the first current transformer is configured to detect a current of the outgoing line;
wherein the plurality of branches comprise a grounding transformer branch provided with a grounding transformer and the grounding transformer neutral-point device; the grounding transformer neutral-point device comprises a disconnector, a circuit breaker and a resistor which are connected in sequence; a high voltage side of the grounding transformer is connected to the bus, and a neutral point of the grounding transformer is grounded sequentially through the disconnector, the circuit breaker and the resistor;
wherein the grounding protection apparatus is configured to: acquire the voltage of the bus and the current of the outgoing line, perform amplitude-phase comparison; acquire a closed/open state of the circuit breaker, and determine whether a grid side connected to the outgoing line has a ground fault to obtain a first determination result; generate a corresponding open/close command according to the first determination result and send the open/close command to the circuit breaker;
wherein the circuit breaker performs a corresponding opening/closing operation according to the open/close command;
the grounding protection apparatus comprises a processing module, and an analog input acquisition module, a binary input acquisition module and an output module which are respectively connected to the processing module;
wherein the analog input acquisition module comprises a first interface of the analog input acquisition module and a tenth interface of the analog input acquisition module; the first interface of the analog input acquisition module is connected to the first current transformer;
the tenth interface of the analog input acquisition module is connected to the potential transformer;
the binary input acquisition module comprises a first interface of the binary input acquisition module, and the first interface of the binary input acquisition module is connected to the circuit breaker and configured to acquire the closed/open state of the circuit breaker;
the output module comprises a fifth interface of the output module and a sixth interface of the output module, wherein the fifth interface of the output module is connected to a trip circuit of the circuit breaker and configured to output an open command, and the sixth interface of the output module is connected to a close circuit of the circuit breaker to output a close command;
the processing module comprises a first processing circuit and a second processing circuit connected in parallel, and the output module comprises an output relay and a starting relay; the output relay comprises a first output relay, a second output relay, a third output relay, a fourth output relay, a fifth output relay and a sixth output relay; the fifth output relay is the fifth interface of the output module; the sixth output relay is the sixth interface of the output module;
the first processing circuit comprises a first analog-to-digital conversion module and a first processor which are connected in sequence, and the second processing circuit comprises a second analog-to-digital conversion module and a second processor which are connected in sequence;
the first processor is respectively connected to the first output relay, the second output relay, the third output relay, the fourth output relay, the fifth output relay and the sixth output relay; the second processor is connected to the starting relay;
the starting relay controls whether a positive power supply of the output relay is applied;
the plurality of branches further comprise a collector line and an SVG line; the collector line is provided with a second current transformer, and the SVG line is provided with a third current transformer; the grounding transformer branch is provided with a fourth current transformer arranged between the grounding transformer and the bus;
the second current transformer, the third current transformer and the fourth current transformer are respectively configured to detect a current of the collector line, a current of the SVG line, and a current of the grounding transformer branch;
the grounding protection apparatus performs threshold comparison on the voltage of the bus when the circuit breaker is in the open state, and if the voltage of the bus is greater than or equal to a preset threshold, the grounding protection apparatus performs calculation and amplitude-phase comparison on the voltage of the bus, the current of the outgoing line, the current of the collector line, the current of the SVG line, and the current of the grounding transformer branch to determine whether the bus has a ground fault and obtain a second determination result;
the grounding protection apparatus performs threshold comparison on the voltage of the bus when the circuit breaker is in the open state, and if the voltage of the bus is greater than or equal to the preset threshold, the grounding protection apparatus performs calculation and amplitude-phase comparison on the voltage of the bus and the current of the collector line to determine whether the collector line has a ground fault and obtain a third determination result;
the grounding protection apparatus performs threshold comparison on the voltage of the bus when the circuit breaker is in the open state, and if the voltage of the bus is greater than or equal to the preset threshold, the grounding protection apparatus performs calculation and amplitude-phase comparison on the voltage of the bus and the current of the SVG line to determine whether the SVG line has a ground fault and obtain a fourth determination result;
the grounding protection apparatus performs threshold comparison on the voltage of the bus when the circuit breaker is in the open state, and if the voltage of the bus is greater than or equal to the preset threshold, the grounding protection apparatus performs calculation and amplitude-phase comparison on the voltage of the bus and the current of the grounding transformer branch to determine whether the grounding transformer branch has a ground fault and obtain a fifth determination result.

2-4. (canceled)

5. The new energy power station grounding protection system according to claim 1, wherein the analog input acquisition module further comprises a second interface of the analog input acquisition module, a third interface of the analog input acquisition module and a fourth interface of the analog input acquisition module, wherein:
the second interface of the analog input acquisition module is connected to the second current transformer;
the third interface of the analog input acquisition module is connected to the third current transformer;
the fourth interface of the analog input acquisition module is connected to the fourth current transformer.

6. The new energy power station grounding protection system according to claim 1, wherein the output module further comprises a first interface of the output module, a second interface of the output module, a third interface of the output module and a fourth interface of the output module; the first interface of the output module is the first output relay; the second interface of the output module is the second output relay; the third interface of the output module is the third output relay; the fourth interface of the output module is the fourth output relay;
the outgoing line is also provided with a first circuit breaker located between the first current transformer and the bus; a trip circuit of the first circuit breaker is connected to the first interface of the output module;
the collector line is also provided with a second circuit breaker located between the second current transformer and the bus; a trip circuit of the second circuit breaker is connected to the second interface of the output module;
the SVG line is also provided with a third circuit breaker located between the third current transformer and the bus; a trip circuit of the third circuit breaker is connected to the third interface of the output module;
the grounding transformer branch is also provided with a fourth circuit breaker located between the fourth current transformer and the bus; a trip circuit of the fourth circuit breaker is connected to the fourth interface of the output module;
the processing module is configured to send a protection trip signal to the first circuit breaker, the second circuit breaker, the third circuit breaker, the fourth circuit breaker through the first interface of the output module, the second interface of the output module, the third interface of the output module and the fourth module of the output module respectively when the second determination result is that the bus has a ground fault;
the processing module is further configured to send a protection trip signal to the second circuit breaker through the second interface of the output module when the third determination result is that the collector line has a ground fault;
the processing module is further configured to send a protection trip signal to the third circuit breaker through the third interface of the output module when the fourth determination result is that the SVG line has a ground fault;
the processing module is further configured to send a protection trip signal to the fourth circuit breaker through the fourth interface of the output module when the fifth determination result is that the grounding transformer branch has a ground fault.

7. The new energy power station grounding protection system according to claim 6, wherein the new energy power station grounding protection system further comprises a fifth current transformer arranged between the resistor and the ground, and a temperature control switch in a resistance chamber where the resistor is located;
the analog input acquisition module further comprises a fifth interface of the analog input acquisition module, and the fifth interface of the analog input acquisition module is connected to the fifth current transformer;
the fifth current transformer is configured to detect a current of the resistor;
a second interface of the binary input acquisition module is connected to the temperature control switch and configured to acquire a state of the temperature control switch;
the processing module is configured to calculate an accumulated heat of the resistor according to the current of the resistor when the temperature control switch is in a closed state, and send an open command to the circuit breaker through the fifth interface of the output module when the accumulated heat of the resistor is greater than or equal to a preset heat threshold, and after a delay of a preset time period, send a protection trip signal to the fourth circuit breaker through the fourth interface of the output module.

8. A new energy power station grounding protection method, applied to a new energy power station grounding protection system according to claim 1, wherein the new energy power station grounding protection method comprises:
using a potential transformer, to detect a voltage of a bus, and send the voltage of the bus to a grounding protection apparatus; using a first current transformer to detect a current of an outgoing line and send the current of the outgoing line to the grounding protection apparatus;
using the grounding protection apparatus to acquire the voltage of the bus and the current of the outgoing line, perform amplitude-phase comparison, acquire a closed/open state of a circuit breaker, and determine whether a grid side connected to the outgoing line has a ground fault to obtain a first determination result; generate a corresponding open/close command according to the first determination result and send the open/close command to the circuit breaker; and
performing, by the circuit breaker, a corresponding opening/closing operation according to the open/close command.

9-14. (canceled)

15. An electronic device comprising: at least one processor and a memory;
wherein the memory store computer-executable instructions;
wherein the at least one processor executes the computer-executable instructions stored in the memory to cause the at least one processor to execute the new energy power station grounding protection method according to claim 8.

16. A non-transitory computer-readable storage medium, wherein the non-transitory computer-readable storage medium has computer-executable instructions stored therein, and the computer-executable instructions, when executed by a processor, are used to implement the new energy power station grounding protection method according to claim 8.

17. A new energy power station grounding protection method, applied to a new energy power station grounding protection system according to claim 2, wherein the new energy power station grounding protection method comprises:
using a potential transformer to detect a voltage of a bus, and send the voltage of the bus to a grounding protection apparatus; using a first current transformer to detect a current of an outgoing line and send the current of the outgoing line to the grounding protection apparatus;
using the grounding protection apparatus to acquire the voltage of the bus and the current of the outgoing line, perform amplitude-phase comparison, acquire a closed/open state of a circuit breaker, and determine whether a grid side connected to the outgoing line has a ground fault to obtain a first determination result, and generate a corresponding open/close command according to the first determination result and send the open/close command to the circuit breaker;
performing, by the circuit breaker, a corresponding opening/closing operation according to the open/close command.

18. A new energy power station grounding protection method, applied to a new energy power station grounding protection system according to claim 3, wherein the new energy power station grounding protection method comprises:
using a potential transformer to detect a voltage of a bus, and send the voltage of the bus to a grounding protection apparatus; using a first current transformer to detect a current of an outgoing line and send the current of the outgoing line to the grounding protection apparatus;
using the grounding protection apparatus to acquire the voltage of the bus and the current of the outgoing line, perform amplitude-phase comparison, acquire a closed/open state of a circuit breaker, and determine whether a grid side connected to the outgoing line has a ground fault to obtain a first determination result, and generate a corresponding open/close command according to the first determination result and send the open/close command to the circuit breaker;
performing, by the circuit breaker, a corresponding opening/closing operation according to the open/close command.

19. A new energy power station grounding protection method, applied to a new energy power station grounding protection system according to claim 4, wherein the new energy power station grounding protection method comprises:
using a potential transformer to detect a voltage of a bus, and send the voltage of the bus to a grounding protection apparatus; using a first current transformer to detect a current of an outgoing line and send the current of the outgoing line to the grounding protection apparatus;
using the grounding protection apparatus to acquire the voltage of the bus and the current of the outgoing line, perform amplitude-phase comparison, acquire a closed/open state of a circuit breaker, and determine whether a grid side connected to the outgoing line has a ground fault to obtain a first determination result, and generate a corresponding open/close command according to the first determination result and send the open/close command to the circuit breaker;
performing, by the circuit breaker, a corresponding opening/closing operation according to the open/close command.
